(19) United States
(12) Patent Application Publication
(10) Pub. No.: US 2010/0022082 A1
(43) Pub. Date: Jan. 28, 2010

(54) Method for making a nanotube-based electrical connection between two facing surfaces

(75) Inventor: Didier Louis, Coublevie (FR)

Correspondence Address: OLIFF & BERRIDGE, PLC, P.O. BOX 320850, ALEXANDRIA, VA, 22320-4850, US

(73) Assignee: COMMISSARIAT A L'ENERGIE ATOMIQUE, Paris (FR)

(21) Appl. No.: 12/314,815

(22) Filed: Dec. 17, 2008

(30) Foreign Application Priority Data
Dec. 20, 2007 (FR) 07 08956

(51) Int. Cl. H01L 21/768

(52) U.S. Cl. 438/618; 257/E21.575; 977/742

(57) ABSTRACT

Facing surfaces made from semiconductor material are formed and then transformed into a porous semiconductor. The porous semiconductor is then transformed into a porous metallic material by silicidation. The porous metallic material then acts as catalyst for growth of the carbon nanotubes which electrically connect the facing surfaces made from porous metallic material.

### BACKGROUND OF THE INVENTION

The invention relates to a method for making an electrical connection between two facing surfaces by means of carbon nanotubes, the method comprising formation of said surfaces from catalyst material and growth of the nanotubes from said surfaces.

### STATE OF THE ART

Carbon nanotubes are currently the subject of intensive research efforts as their monoatomic cylindrical structure gives them exceptional properties on the nanometric scale. To withstand the stresses imposed by size reduction and complexification of the integration parameters, the use of carbon nanotubes as nanometric metal wires for the electrical connections has been envisaged.

However, to compete with copper interconnections, a density of 10¹² nanotubes/cm² has to be attained. Such a density can only be achieved by forcing the location of the nanotubes, i.e. by forcing growth of nanotubes having a small diameter and close to one another. In conventional manner, the diameter of the carbon nanotubes is comprised between 5 and 15 nm, typically 8 nm for densities of about 5*10¹² nanotubes/cm².

In conventional manner, growth of the carbon nanotubes was achieved from a continuous layer of catalyst material deposited and patterned on a substrate. However, growth of nanotubes from a layer is chaotic and it is difficult to achieve a sufficient nanotube density. As the available surface is large, most of the nanotubes in fact present a diameter and distribution incompatible with the required density.

To increase the nanotube density, another approach consists in annealing a layer of catalyst material of Cobalt, Nickel or Iron type to form a lattice of clusters of small size on the substrate or in depositing these clusters directly. The size of the clusters then determines the size of the nanotubes. This technique does not however enable a sufficient density to be achieved with clusters of small size to obtain a nanotube density that is sufficient to compete with current metallic materials.

### OBJECT OF THE INVENTION

One object of the invention is to provide a method for making a nanotube-based electrical connection that is easy to implement and presents a high nanotube density.

The method according to the invention is characterized by the appended claims and more particularly by the fact that the catalyst material is a porous metallic material obtained by reaction of a porous semiconductor layer and a metal.

### BRIEF DESCRIPTION OF THE DRAWINGS

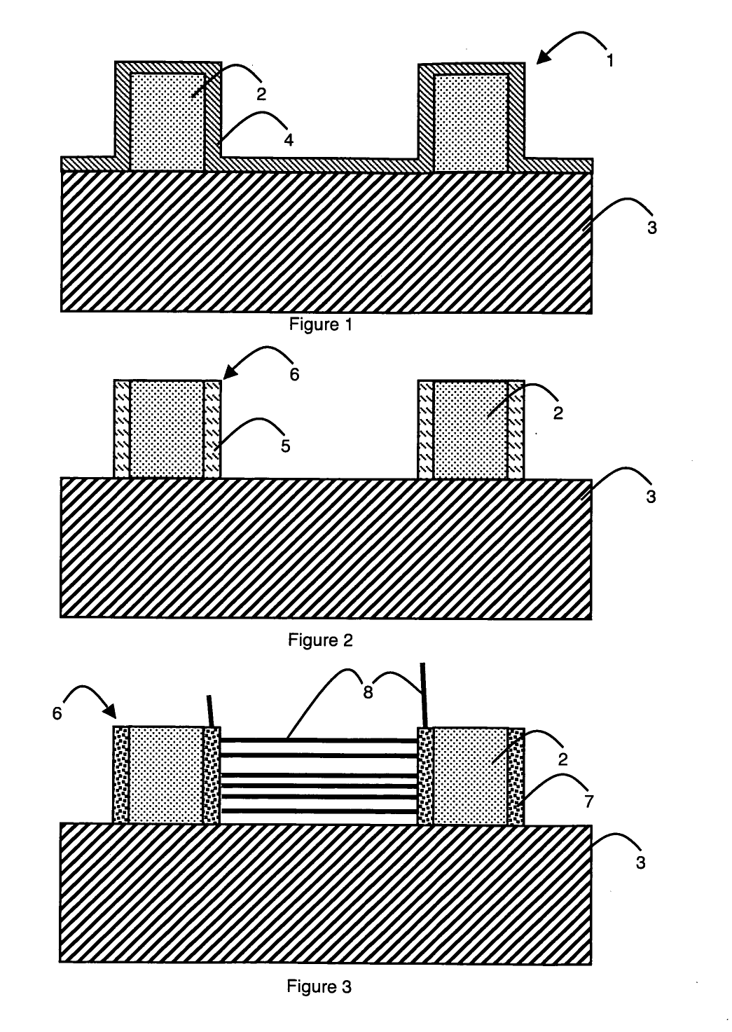

Other advantages and features will become more clearly apparent from the following description of a particular embodiment of the invention given for non-restrictive example purposes only and represented in the accompanying drawings in which FIGS. 1 to 5 schematically represent, in cross-section, the successive steps of a particular embodiment of the method according to the invention.

### DESCRIPTION OF A PREFERRED EMBODIMENT OF THE INVENTION

As illustrated in FIG. 1, in an integrated circuit, patterns 1 made from dielectric material 2 are formed in a substrate 3 which may be made from silicon. Substrate 3 can comprise microelectronic chips, finalized or not, and be covered by an encapsulation layer or a metallic interconnection level. The layer forming the top surface of substrate 3 is advantageously chosen such as to enable selective patterning of the patterns 1 of dielectric material 2. Dielectric material 2 is a conventional microelectronics industry material, for example a silicon oxide-base material, deposited by chemical vapor deposition, plasma enhanced chemical vapor deposition or by spin-coating. The dielectric material can also be silicon nitride-based. Patterns 1 formed on substrate 3 have for example the form of strips or pillars.

A layer of semiconductor material 4, for example silicon or a silicon-germanium alloy, is deposited in non-selective manner on substrate 3 and patterns 1. Deposition is performed in conventional manner, for example by chemical vapor deposition or by plasma enhanced chemical vapor deposition. Semiconductor material 4 then forms a continuous film. Semiconductor material 4 can be intrinsic or doped, amorphous or polycrystalline. Doping of semiconductor material 4 is performed in conventional manner, for example performed with boron. The thickness of layer 4 is typically comprised between 10 and 100 nm, but it can also be thicker.

The layer of semiconductor material 4 then undergoes electrochemical etching, for example electrolysis, in a hydrofluoric acid bath to make it porous. The layer of semiconductor material 4 is thereby transformed into a layer of porous semiconductor material 5. When the layer 4 is made of silicon, the latter is transformed into porous silicon. The density of pores contained in the layer of porous semiconductor material 5 depends on the nature of the deposited semiconductor material 4 (crystallinity, doping . . . ) and on the conditions of the electrochemical etching (current density, hydrofluoric acid concentration, temperature, etc).

The layer of porous semiconductor material 5 is then patterned in conventional manner, preferably by plasma etching, to form spacers 6 that are situated only on the side edges of patterns 1 of dielectric material 2. Spacers 6 then form vertical walls made from porous semiconductor material 5, perpendicular to substrate 3, as illustrated in FIG. 2.

A metal is deposited in conventional manner on the assembly (substrate 3 and patterns 2), for example in non-selective manner. It therefore covers the layer of porous semiconductor material 5. Heat treatment is then performed, preferably at a temperature of less than 400° C., to trigger a reaction between the metal and porous semiconductor material 5 and to form a porous metallic material 7. The metal used to achieve porous metallic material 7 is preferably chosen from Co, Ni, Pt and Fe. In this case, the porous metallic material obtained from porous silicon is a silicide such as CoSi₂, NiSi, PtSi or FeSi. The metal that has not reacted, in particular with the semiconductor material, is then eliminated in conventional manner, for example by wet channel removal.

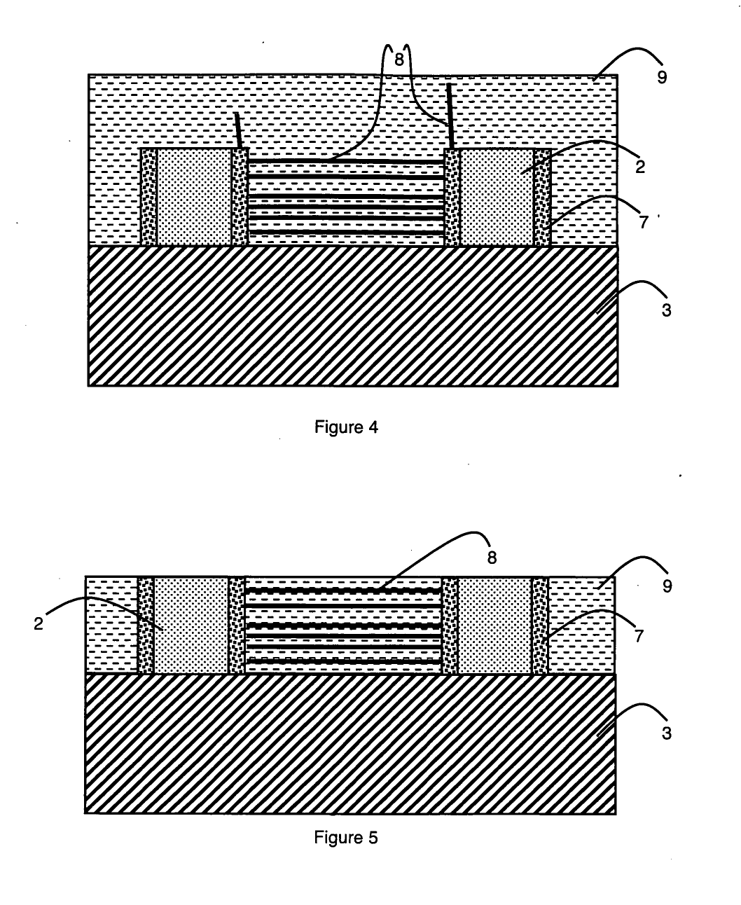

As illustrated in FIGS. 2 and 3, the vertical walls made from porous semiconductor material 5, for example from silicon, are thereby transformed into vertical walls of porous metallic material 7. When the reaction takes place between the metal and the porous semiconductor material, a part of the pores were obstructed. However, pores and free spaces still remain at the surface of the spacers. The size of the pores is typically comprised between 2 and 100 nm with a density that is comprised between 10⁷ and 10¹² pores/cm².

Porous metallic material 7 then acts as catalyst material for growth of nanotubes 8 between the adjacent vertical walls. This growth is achieved (FIG. 3), for example by chemical vapor deposition, essentially from one vertical surface to the facing vertical surface. Nanotubes 8, that are electrically conducting, grow from porous metallic material 7 from areas located between the pores remaining at the surface of material 7. The number and diameter of the nanotubes are determined by the density of pores and by the dimensions of the surface areas situated between the pores. Most of nanotubes 8 therefore have a horizontal growth. The method for growing the nanotubes can be performed by chemical vapor deposition or by plasma enhanced chemical vapor deposition. The deposition temperature is typically about 450-500° C. with an acetylene-based gaseous composition. Ethylene or toluene can for example also be used. The growth temperature of the carbon nanotubes is chosen such as not to cause decomposition of porous metallic material 7 formed.

Substantially horizontal nanotubes 8 thus connect two facing vertical surfaces arranged on substrate 3. The use of a porous catalyst material thereby enables a large density of horizontal nanotubes to be obtained, consequently increasing the current density able to flow in the electrical connection thus formed.

A coating layer 9 is then deposited on the assembly (substrate 3, patterns 1 and nanotubes 8). Coating layer 9, advantageously made from dielectric material, at least partially fills the gap comprised between the facing vertical surfaces inside which nanotubes 8 are located. In FIG. 4, nanotubes 8 and patterns 1 are completely coated in layer 9.

Advantageously, a polishing step, for example chemical mechanical polishing, is performed to planarize coating layer 9 and eliminate nanotubes 8 that are upwardly salient from patterns 1 of dielectric material 2. Once the structure has been planarized, a new layer of dielectric material can be deposited to finalize the structure or to enable another interconnection level to be made in the integrated circuit.

The semiconductor is advantageously silicon, made porous by electrolysis and then silicided to form a porous silicide acting as catalyst. The invention nevertheless applies to any semiconductor able to be transformed into a porous metallic material able to act as catalyst for growth of nanotubes, in particular carbon nanotubes.

1. A method for making an electrical connection between two facing surfaces by means of carbon nanotubes, the method comprising formation of said catalyst material surfaces, a porous metallic material obtained by reaction of a porous semiconductor layer and a metal, and growing the nanotubes from said surfaces.

2. The method according to claim 1, wherein the porous metallic material is a silicide.

3. The method according to claim 1, wherein the metal is chosen from Co, Ni, Pt and Fe.

4. The method according to claim 1, successively comprising on a substrate:
forming patterns of dielectric material,
depositing a layer of semiconductor material,
transforming said semiconductor material into a porous semiconductor,
forming at least two spacers perpendicular to the substrate constituting said facing surfaces, by etching of the porous semiconductor layer,
siliciding the porous semiconductor spacers by means of a metal, and
growing the nanotubes between the spacers, parallel to the substrate.
